(19) United States
(12) Patent Application Publication
(10) Pub. No.: US 2010/0237895 A1
(43) Pub. Date: Sep. 23, 2010

(54) System and method for characterizing solar cell conversion performance and detecting defects in a solar cell

(76) Inventor: Kyo Young Chung, San Jose, CA (US)

Correspondence Address: Kyo Young Chung, 6838 Westmoor Way, San Jose, CA, 95129, US

(21) Appl. No.: 12/592,798

(22) Filed: Dec. 2, 2009

Related U.S. Application Data
(63) Continuation-in-part of application No. 12/407,737, filed on Mar. 19, 2009.

(51) Int. Cl. G01R 31/26

(52) U.S. Cl. 324/766

(57) ABSTRACT

A system and method for characterizing the solar cell conversion performance and detecting a defect in a solar cell includes applying an optical test signal to the solar cell using the multiple-scanning method, measuring the solar cell photocurrent in response to the solar cell illumination by the multiple-scanning method, and detecting a defect and finding its location based on the characteristic mapping of solar cell photocurrent, which is obtained by the multiple-scanning method through the divisional control of light transmittance by the LVP (light valve panel). The defect may be a solar cell subsection which has abnormally low photocurrent below a critical value and can be caused by a short between the emitter and the base of solar cell. The LVP may be realized in any one of a variety of ways. For example, the LVP may be a flat-panel display such as AMLCD (Active-Matrix Liquid Crystal Display) and AMOLED (Active-Matrix Organic Light Emitting Diode).

### CROSS REFERENCE TO RELATED APPLICATION

This is a continuation-in-part of the application Ser. No. 12/407,737.

### BACKGROUND OF THE INVENTION

1. Field of the Invention

This invention generally relates to testing and characterizing electronic circuits, and more particularly to a system and method for characterizing solar cell conversion performance and detecting defects in one or more solar cells.

2. Background of the Related Art

Solar cell is one of the promising ones among the renewable energy resources as an alternative to fossil fuels. A large barrier against the commercial expansion of the solar cell, however, is the high price of the solar-cell module, which may be caused by low yield of solar cell manufacturing.

During the manufacturing process of solar cell, defects may develop which, if left un-repaired, may diminish the number of working units and degrade the conversion efficiency of solar cell and/or reduce the manufacturing yield. These defects include electrical shorts between the top electrode, which is also called as the emitter, and the bottom electrode, which is also called as the base.

Once a defect like the short between the emitter and the base has been located in a solar cell, it can be repaired by removing or isolating the short and making the rest of solar cell area functional.

In order to monitor the manufacturing process of solar cell, one needs to characterize the performance of solar cell on various locations of solar cell.

In view of the foregoing considerations, it is apparent that there is a need for a system and method for applying the test signals to solar cell, monitoring measurement characteristics, characterizing solar cell performance, detecting the existence of a defect in a solar cell, finding the location of the defect, and repairing the solar cell without disturbing other portions of the solar cell that are properly functioning. The need to automatically test and repair the defects becomes more important as the number and size of solar cells increase on a substrate.

### SUMMARY OF THE INVENTION

An object of the present invention is to improve the accuracy and efficiency of testing and characterizing electronic circuits including ones containing solar cells.

Another object of the present invention is to provide a system and method for accurately detecting defects in a solar cell.

Another object of the present invention is to provide a system and method for precisely determining the location of a defect in a solar cell during a testing procedure.

Another object of the present invention is to provide a system and method for characterizing the performance of solar cell conversion efficiency.

These and other objects and advantages of the present invention are achieved by providing the method for characterizing the performance of solar cell conversion efficiency and detecting a defect in solar cell which, in accordance with one embodiment, includes applying optical test signals to the solar cell surface by the multiple-scanning method, measuring the photocurrent as the electrical response to the illumination by the multiple-scanning method, detecting a defect with its location based on performance characterization of solar cell conversion efficiency such as characteristic mapping of solar cell photocurrent. The defect may be a solar cell subsection which has abnormally low photocurrent below a critical value and can be caused by a short between the emitter and the base of solar cell.

In accordance with another embodiment, the present invention is a system for characterizing the performance of solar cell conversion efficiency and detecting a defect in solar cell. The system includes an optical signal generator for applying the optical test signals to the solar cell surface by the multiple-scanning method, a current meter which measures the photocurrent in response to the solar cell illumination by the multiple-scanning method, and a controller, which controls the optical signal generator and the current meter, detects a defect, and finds its location based on the characteristic mapping of solar cell photocurrent measured.

Additional advantages, objects, and features of the invention will be set forth in part in the description which follows and in part will become apparent to those having ordinary skill in the art upon examination of the following or may be learned from practice of the invention. The objects and advantages of the invention may be realized and attained as particularly pointed out in the appended claims.

### BRIEF DESCRIPTION OF THE DRAWINGS

The invention will be described in detail with reference to the following drawings in which like reference numerals refer to like elements wherein:

FIG. 1 is a block diagram of the test and repair apparatus illustrating a structure including a light valve panel, in accordance with the present invention;

FIG. 2 is a solar cell current-voltage characteristic when the solar cell is illuminated;

FIG. 3 is a simple view of a cross section of TFT-LCD panel;

FIG. 4 is a simple top view of a part of TFT back plane;

FIG. 5 is a flow chart of solar cell test, in accordance with the present invention;

FIG. 6 is an equivalent circuit of a solar cell;

FIG. 7 is an exemplary cross-section of a solar cell whose defect is isolated;

FIG. 8 is an example of spectral response of solar cell;

FIG. 9 is an example of the zonal illumination by the backlight;

FIG. 10 is an example of a LED array and its driving circuitry for matrix driving of LEDs.

### DETAILED DESCRIPTION OF PREFERRED EMBODIMENTS

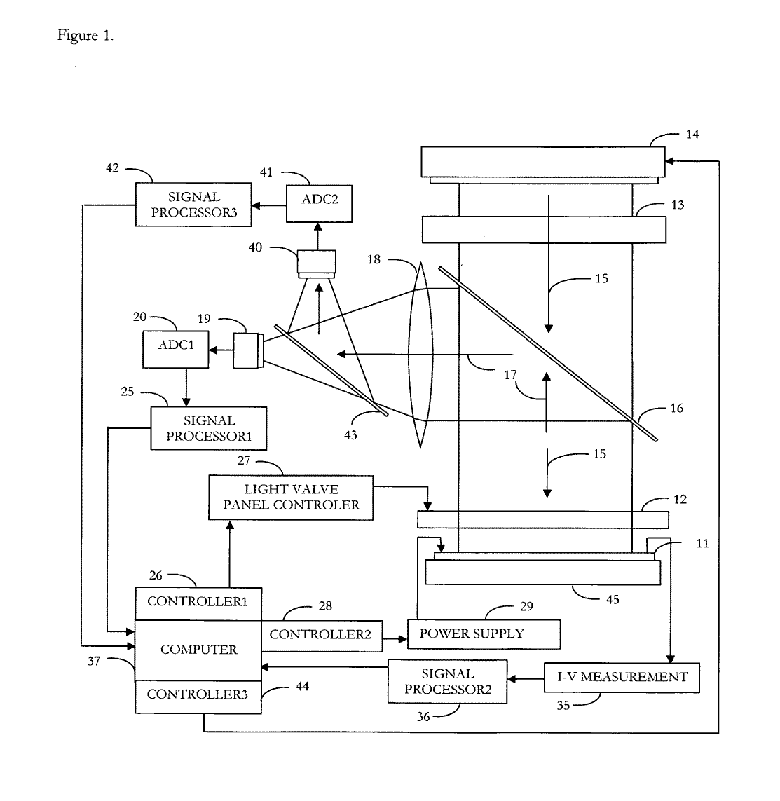

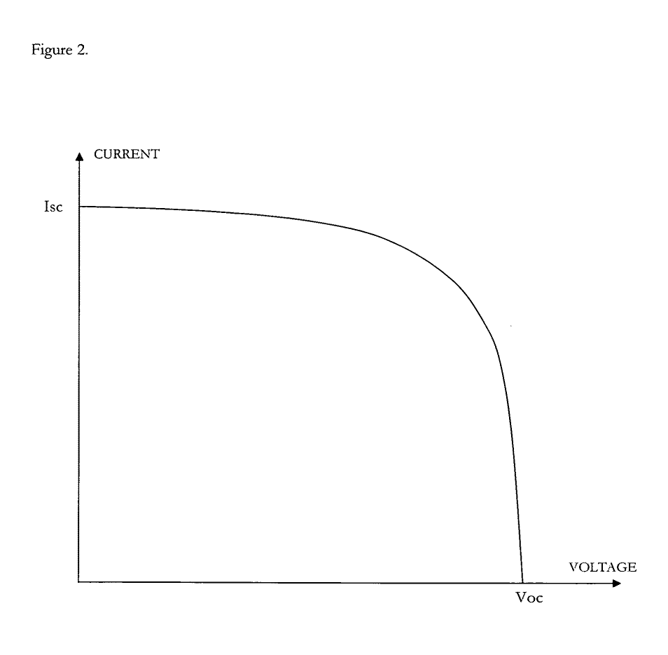

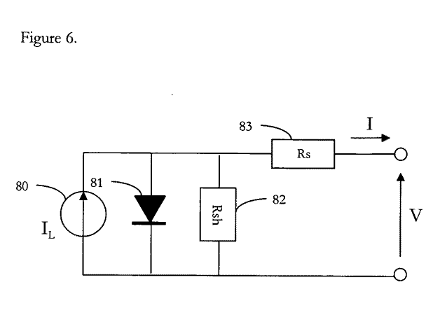

FIG. 1 is a block diagram of the test apparatus illustrating a structure to test and repair solar cells. A solar cell is tested after manufacturing process is completed to give functionality of current generation when the surface of solar cell receives light. In the FIG. 1 the solar cell under test (SUT) 11 may be tested in two modes, independently or in serial modes. The SUT can receive the optical input beam 15, which is generated by the optical energy source 14 and goes through the light valve panel (LVP) 12. The optical input beam 15, if necessary for collimation of light, may be expanded and collimated by the beam expander 13. If the SUT has no defect and works properly, then it generates photo-induced current and the I-V (current-voltage) measurement unit 35 measures the current-voltage characteristic as shown in FIG. 2, where Isc and Voc stand for a short circuit current and an open circuit voltage, respectively. FIG. 6 shows the equivalent circuit of a solar cell, where a solar cell is represented by a current source 80, a diode 81, a shunt resistor 82, and a series resistor 83. When there is a process anomaly and process defect is created, then the measured I-V characteristic shows abnormal measurement data such as low Isc, low Voc, high series resistance, low shunt resistance, and/or large deviation of curve slopes near Isc and/or Voc from normal slopes, which ideally show almost vertical crossings at the x and y axes. The measurement data is delivered to the computer 37 through the signal processor 36, which communicates with the computer 37 and the I-V measurement unit 35.

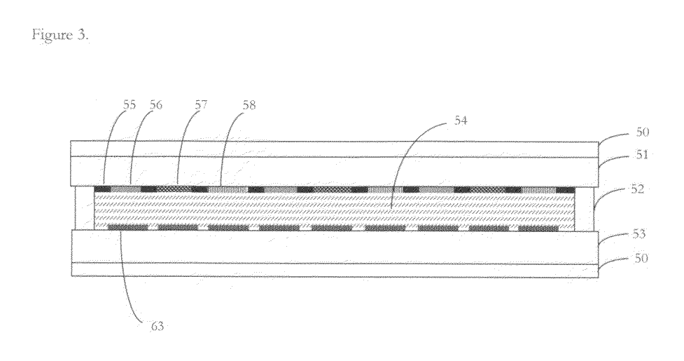

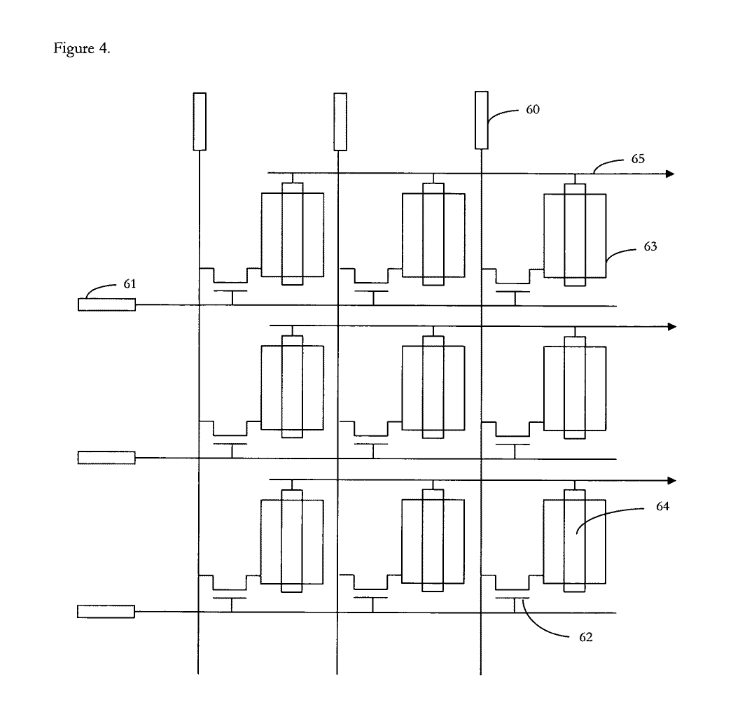

The presence of a defect in a solar cell can be detected by observing whether the measured solar cell performance parameters such as Isc, Voc, series resistance, shunt resistance, the curve slopes, and the fill factor which is defined as the ratio (the maximum value of CURRENT*VOLTAGE)/(Isc*Voc) in FIG. 2 are beyond certain criteria. The solar cell with a defect such as a short defect between an emitter and a base can be repaired by removing or isolating the defect from the normal portion of solar cell. However, in order to repair the defect, one needs to find the location of the defect and position identifying method is required. The LVP can provide the position identifying method if the LVP has the capability of matrix-driven light control. For example, the panel used for passive matrix driven liquid crystal display (PMLCD) or active matrix driven liquid crystal display (AMLCD) such as Thin Film Transistor driven LCD (TFT-LCD) or Diode driven LCD has the capability of controlling the light passage in very small size unit, which is called a pixel, in a matrix format. FIG. 3 shows a simple view of a cross section of TFT-LCD panel, where the color filter front plane 51 has a black matrix 55 which blocks the light and a patterned color filter array which is composed of an array of red color dot 56, an array of green color dot 57, and an array of blue color dot 58, the TFT back plane 53 has an array of transparent pixel electrode 63 and TFT and storage capacitor, which are 62 and 64 respectively in FIG. 4, the sealant 52 confines the liquid crystal 54 between the color filter plane and TFT back plane, and the polarizer 50 is attached to the color filter plane and TFT back plane. FIG. 4 shows a simple top view of a part of TFT back plane, where the pad for data line 60, the pad for gate line 61, the TFT 62, the transparent pixel electrode 63, the storage capacitor 64, and the common line 65 are shown. The TFT-LCD panel can control the light passage through its pixel electrodes with control factors such as the position and number of pixels, the gray scale, and color. Thus, initial test to determine the presence of a defect in solar cell can be done with all the pixel electrodes transmitting the light with full intensity. The color filter array on the color filter front plane 51 may not be necessary and may be absent as in the case where color is not needed but higher light intensity is required. If defect presence is decided, then another test can be performed to find the defect location varying the control factors. A solar cell can be, in general, divided into multiple smaller solar cells with electrical resistance among their electrodes especially on the front surface where the resistance value can be high compared to the back surface. For example, the solar cell can be divided into four quadrants and the optical input beam is applied to the solar cell surface by the unit of quadrant by having the LVP transmit the light by quadrant and the current or current-voltage characteristic is measured for each quadrant to decide which quadrant contains the defect. The quadrant that has the defect will show the measurement of the worst solar cell performance of light-to-current conversion among the four quadrants. This division of solar cell can be done down to each pixel of TFT-LCD unit because the TFT-LCD panel has a capability to drive each individual pixel.

In another mode of operation electroluminescence of normal part of solar cell and luminance of abnormal part carrying high current caused by a defect such as the short between an emitter and a base of solar cell can be used for defect detection of solar cell. The electrical signal is applied between an emitter and a base of solar cell from the power supply unit 29, which is controlled by the computer through the controller 28. The light beam generated from the solar cell can be transmitted to the optical sensor 19 and/or the optical sensor 40 through the LVP 12 and the focusing lens 18. The choice of the light beam's route depends on its wavelength and the wavelength characteristic of the filter mirror 43. The output of optical sensor 19 (40) is delivered to the computer through the ADC (analog to digital converter) 20 (41) and the signal processor 25 (42). If there is no defect in solar cell, then the light beam generated from solar cell has expected intensity and frequency from normal electroluminescence. If there is a defect in the solar cell, then the light beam generated from solar cell does not have the intensity and frequency from normal electroluminescence but has the intensity and frequency specific to the defect kind such as a short defect between an emitter and a base of solar cell. Thus, the optical sensors generate different output signals from normal signals when there is a defect in solar cell because its output signal depends on the intensity and wavelength of sensed light. Thus, the presence of a defect in a solar cell can be detected by observing whether the output intensity of the optical sensor that has sensing characteristic tuned to normal electroluminescence of solar cell is above certain criteria and the output intensity of the optical sensor that has sensing characteristic tuned to abnormal luminescence of solar cell is below certain criteria. In order to repair the defect, one needs to find the location of the defect and position identifying method is required. The position-dependent luminance and electroluminescence of solar cell may be measured by a camera which has a sensor array sensitive to the measured signal wavelength and is used to take the image of luminescence and electroluminescence of solar cell. The position-dependent luminance and electroluminescence may also be measured by using a simple aerial sensor and the LVP. The LVP can provide the position identifying method if the LVP has the capability of matrix-driven light control as described above. Thus, initial test to determine the presence of a defect in solar cell can be done with all the pixels transmitting the light with full intensity. If defect presence is decided, then another test can be performed to find the defect location varying the control factors of the LVP. For example, the solar cell can be divided into four quadrants and the optical output beam from the solar cell surface is transmitted to the optical sensors by the unit of quadrant by having the LVP transmit the light by quadrant and the light intensity is measured for each quadrant to decide which quadrant contains the defect. The quadrant that has a defect such as a short defect between the emitter and the base will show the measurement of the lowest solar cell electroluminescence and the highest luminance from the short defect. This division of solar cell can be done down to each pixel unit because the TFT-LCD panel has a capability to drive each individual pixel as described above.

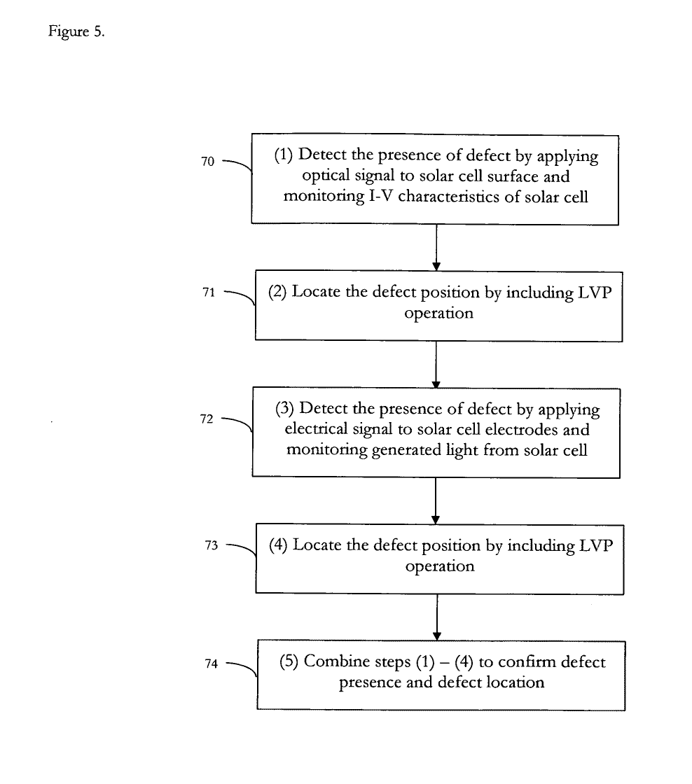

The defect detection and finding the defect location in solar cell can be performed in two modes of operation as described above; one mode is to apply the optical beam to the solar cell surface through the LVP and monitor the current or current-voltage characteristics and another mode is to apply the voltage signal between an emitter and a base of solar cell and monitor the generated light beam by solar cell that goes through the LVP. These two modes of operation can be done independently or in series to generate individual test results and one can combine those individual test results to yield new test result with better defect detection performance and accuracy. FIG. 5 shows an exemplary flow chart of solar cell test using the two modes of operation.

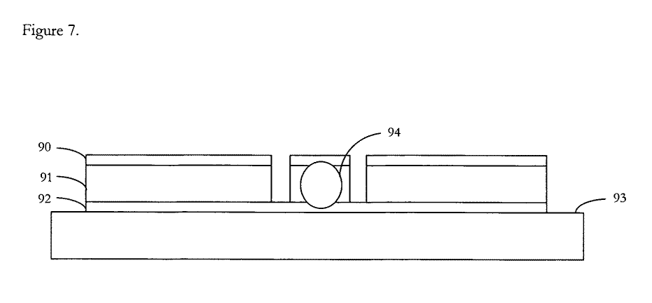

Once the defect location is identified in solar cell, one can repair the solar cell by removing or isolating the defect from normal portion of solar cell as shown in FIG. 7, where a short defect 94 connects a top electrode 90 to a bottom electrode 92 on a substrate 93 through a solar cell semiconductor layer 91. In this example the defect isolation is achieved by cutting the top electrode and the semiconductor layer around the defect. The removing or isolating defects may be performed in any one of variety of ways. For example, laser beam can be used to remove or isolate the defect when scanning capability of either laser head or solar cell under test is provided. Or the removing the short defect between the emitter and the base of solar cell can be done by sending current from the power supply unit 29 between two electrodes, preferably in the reverse direction of solar cell to increase the maximum current to the defect because the electrical signal applied to solar cell in forward direction of solar cell can experience limitation of applied voltage due to low forward threshold voltage of solar cell and this may limit the current increase through the defect. The current sent to solar cell in reverse direction can be directed to the short defect and the heat generated by the current flow can remove the defect. In order to reduce the amount of current flow, one can also use the heat from the additional light beam, which can be either applied to entire solar cell surface or selectively to the defect area using the LVP 12. The optical energy source 14 or another optical energy source with optical guide may be used for this purpose if its output intensity can be controlled by the computer 37 through the controller 44 to provide the required heat for repairing defected solar cell. Additional heat may be applied to the solar cell by raising the temperature of the plate on which the solar cell is placed.

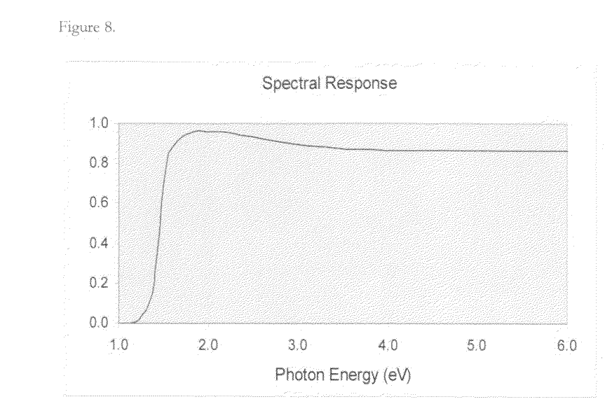

Characterization of solar cell performance includes such methods as current-voltage measurement, spectral response measurement, and quantum efficiency measurement and their characterizing performance may be improved by adding the LVP in the measurement setup, where the LVP's control factors such as the size, position, gray level, and color of the passing test beam can be varied. For example, the solar cell can be divided into four quadrants and the optical input beam is applied to the solar cell surface by the unit of quadrant by having the LVP transmit the light by quadrant and the current or current-voltage characteristic is measured for each quadrant to decide the variation of current or current-voltage characteristic from quadrant to quadrant. This division of solar cell can be done down to each pixel unit because the TFT-LCD panel has a capability to drive each individual pixel. For the current-voltage characteristic measurement, the optical energy source 14 in FIG. 1 may be replaced by a solar simulator which is a light source simulating solar radiation. One may also improve the characterizing performance of the spectral response measurement by adding the LVP in the measurement setup. Spectral response of solar cell shows solar cell's light-to-current conversion efficiency with respect to photon's energy as shown in FIG. 8. For example, the solar cell can be divided into four quadrants and the optical input beam is applied to the solar cell surface by the unit of quadrant by having the LVP transmit the light by quadrant and the spectral response is measured for each quadrant to decide the variation of spectral response from quadrant to quadrant. For the spectral response measurement, the optical energy source 14 in FIG. 1 needs to be replaced by another unit that can provide monochromator and the I-V measurement unit 35 needs to be replaced by another current measuring unit that may include lock-in amplifier.

The divisional control of light transmittance by the LVP can have the advantage of faster detection of the solar cell defect and faster characterization of solar cell performance for process monitoring. The LVP can control the light illuminated on the solar cell surface and thus the solar cell photocurrent generated by the light. The size of transmitted light through the LVP can be changed by changing the size of the bright image window of the LVP and the LVP may be a flat-panel display such as AMLCD (Active-Matrix Liquid Crystal Display) and AMOLED (Active-Matrix Organic Light Emitting Diode). The AMLCD such as TFT-LCD panel may have a backlight of an aerial light source, which replaces the optical energy source 14 and the beam expander 13 in FIG. 1. If emissive flat-panel display such as AMOLED display is used, then there is no need for the backlight or other additional optical energy source and related optical parts. In the divisional control of light transmittance by the LVP, the multiple-scanning method using multiple scans of a solar cell can be done for fast test and characterization, where each scan is composed of the serial repetitions of stepping and illumination of the bright image window of the LVP and solar cell photocurrent measurement. In the first scan the LVP can provide multiple illuminations to an array of the subsection of a solar cell. For example, a solar cell is divided into a 4-by-5 (4 rows by 5 columns) subsection array and the photocurrent is measured for the solar cell while each subsection is illuminated by the bright image window of the LVP. After one photocurrent measurement is done at a subsection, the bright image window moves to a next subsection and repeats the photocurrent measurement during the illumination by the bright image window. One can obtain a 4-by-5 photocurrent array, which can be used for a characteristic mapping of a solar cell, for entire solar cell when 20 repetitions of window stepping/illumination and photocurrent measurement are completed. If there is a subsection with abnormally low photocurrent below a certain critical value, then the subsection can be identified as a defect and reported with its location. If more accurate conversion characterization and defect location are required, then the subsection with abnormally low photocurrent can be further divided into another array of smaller second subsections and rescanned with smaller window stepping/illumination and photocurrent measurement. For example, the subsection with abnormally low photocurrent below the critical value is further divided into a 4-by-5 second subsection array and the photocurrent is measured at each second subsection while it is illuminated to obtain a 4-by-5 photocurrent array, which can be used for the characteristic mapping of the subsection. If there is a second subsection with abnormally low photocurrent below another critical value, then the second subsection can be identified as a defect and reported with its location. This procedure of obtaining the array of photocurrents and identifying the defect and locating its location can be repeated until accurate enough characterization and defect location are obtained. In case of two scans (one 4-by-5 scan for entire solar cell and another 4-by-5 scan for the subsection with abnormally low photocurrent) the total number of measurement times is (4×5+4×5=) 40 when the multiple-scanning method through the divisional control by the LVP is used to locate a defect with the accuracy of 1/(4²×5²)= 1/400. But in case of conventional single serial scan of 4²-by-5² for the same accuracy of 1/400, the total number of measurement times is 400 to locate a defect because the row division number is 4², the column division number is 5², and the total number of stepping/illumination and photocurrent measurement is (4²×5²=) 400. In case of three scans the total number of measurement times is (4×5+4×5+4×5=) 60 when the multiple-scanning method is used to locate a defect with the accuracy of 1/(4³×5³)= 1/8000. But in case of conventional single serial scan the total number of measurement times is (4³×5³=) 8000 to locate a defect with the same accuracy. Therefore one can see the advantage of the multiple-scanning method in lowering the time to locate the solar cell defect. The multiple-scanning method through the divisional control of light transmittance by the LVP described above is based on the further evaluation and characterization of the partial area (subsection) of solar cell where the light-to-current conversion performance is inferior to other solar cell areas (subsections). Thus the multiple-scanning method can be used for process monitoring in the manufacturing facility of solar cell. Collection of data regarding the areas of inferior performance and/or the defect distribution in the solar cell can be achieved by the multiple-scanning method and the data can be used in analyzing the problems and issues in manufacturing processes of solar cell.

The multiple-scanning method through the divisional control of light transmittance by the LVP has another advantage in case of serially configured thin-film solar cell where entire solar cell is divided into sub solar cells and each sub solar cell is connected in a serial mode. In order to generate the photocurrent from this type of solar cell, each and every sub solar cell has to be illuminated to generate the photocurrent because the sub solar cell with the lowest photocurrent limits the photocurrent of entire solar cell. If conventional serial scan is used for this type of solar cell, then each sub solar cell needs to be individually tested with probe contacts made to the emitter and base electrodes of each sub solar cell for its photocurrent measurement. If the multiple-scanning method through the divisional control of light transmittance by the LVP is used, then the probe contacts can be made to the emitter and base electrodes of entire solar cell for photocurrent measurement of each sub solar cell. Because the LVP can have multiple bright image windows with different sizes and shapes at the same time, the subsections of the tested sub solar cell can be scanned with the bright image window of the LVP for photocurrent generation while entire surface areas of other sub solar cells are illuminated by larger bright image windows for generation of their photocurrents, which are larger than the photocurrent of the scanned sub solar cell. The measured photocurrent for entire solar cell is limited by the scanned sub solar cell and reflects the conversion efficiency of the illuminated subsection of the scanned sub solar cell.

In the use of the divisional control of light transmittance by the LVP, one needs to minimize the noise in the photocurrent measurement to improve the performance of the signal-to-noise ratio. One of the causes of the noise is non-ideal dark photocurrent of solar cell. An ideal LVP is to provide complete darkness to the solar cell surface when it is not illuminated and the solar cell should not generate the photocurrent. But in actual application of the LVP, even when the solar cell surface area is supposed to be blocked from any illumination, there is an unintended light illuminated to the solar cell surface due to non-ideal factors such as a light leakage through the LVP and this generates the dark photocurrent. And there is also a noise current in the photocurrent measurement due to non-ideal factors such as current induction to the measurement lead-wires by ambient electromagnetic wave and this adds to the dark photocurrent. In order to minimize the noise in the photocurrent measurement, one can use the dark photocurrent cancellation method, where one measures the dark photocurrent without any bright image window turned on before or after the photocurrent measurement is done with the bright image window turned on and subtracts the dark photocurrent from the measured photocurrent with the bright image window turned on. Thus the dark photocurrent cancellation method gives the photocurrent value without the noise due to the dark photocurrent.

Another cause of the noise is non-uniform illumination of the LVP across different locations of the scanned bright image window and this noise component should be minimized by the photocurrent calibration method. One can express the positional dependency of the photocurrent as

F_{LVP}(x,y)F_{C}(x,y)=F_{I}(x,y) (1)

where F_{LVP}(x,y), F_{C}(x,y), and F_{I}(x,y) are the LVP light intensity illuminating a solar cell subsection, the conversion efficiency of the solar cell subsection, and the corresponding solar cell photocurrent, at the location of x row and y column in the solar cell subsection array. Thus the positional dependency of the solar cell conversion efficiency can be obtained by

F_{C}(x,y)=F_{C}(x,y)/F_{LVP}(x,y) (2)

where F_{I}(x,y) can be obtained by the photocurrent measurement with the divisional control by the LVP and F_{LVP}(x,y) can be obtained by another independent method such as the light intensity measurement of the bright image windows by an instrument such as a luminance meter with the scanning capability. The calibrated photocurrent can be obtained by multiplying F_{C}(x,y) by a constant reference intensity of illumination light. Thus either the positional distribution of the conversion efficiency of the solar cell subsection or the positional distribution of the calibrated photocurrent can be used for the defect detection and the performance characterization of solar cell.

The F_{LVP}(x,y) can also be obtained by the multiple photocurrent measurement method where the photocurrent is measured for many number of solar cells and its average value is used. When the multiple measurements are done and Equation (1) is used for the average values, one can obtain following expression

(1/n)Σ{F_{LVP}(x,y)F_{C}(x,y)}=(1/n)ΣF_{I}(x,y) (3)

where n is the number of measurements and Σ indicates the summation for the n measurements. Since F_{LVP}(x,y) can be constant from measurement to measurement, Equation (3) becomes

F_{LVP}(x,y)(1/n)ΣF_{C}(x,y)=(1/n)ΣF_{I}(x,y) (4).

As the number of measurements increases to a large number, the value of (1/n)Σ F_{C}(x,y) approaches a constant number with respect to (x,y), which is expressed as F_{AC}, and Equation (4) becomes

F_{LVP}(x,y)=F_{AI}(x,y)/F_{AC} (5)

where F_{AI}(x,y) is (1/n)ΣF_{I}(x,y), and from Equations (2) and (5) one obtains

fc(x,y)=Fc(x,y)/F_{AC}=F_{I}(x,y)/F_{AI}(x,y) (6)

where f_{C}(x,y) is the F_{C}(x,y) normalized by F_{AC}. The value of F_{AC} can be obtained by another test method but, without knowing it, the f_{C}(x,y) obtained by the multiple photocurrent measurement method can be used for the defect detection and the performance characterization of solar cell.

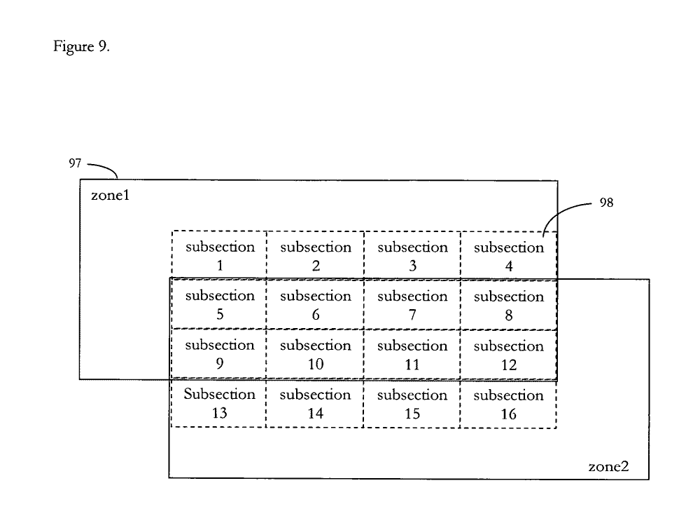

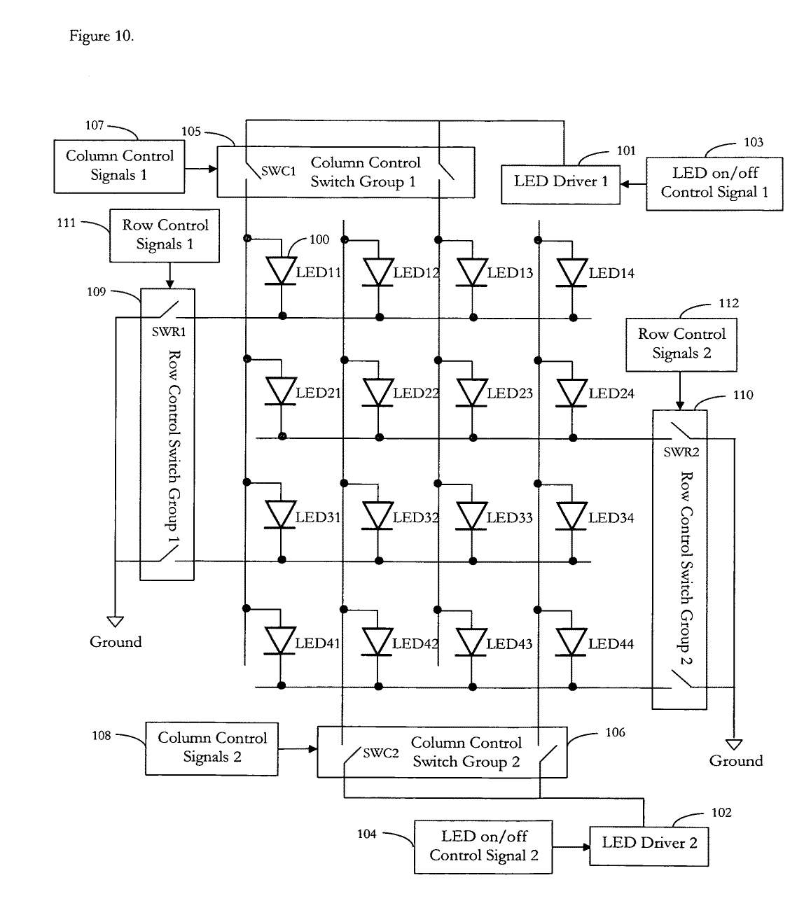

The CCFL (Cold Cathode Fluorescent Lamp) and the array of LEDs (Light Emitting Diodes) have been used for the backlight of TFT-LCD panel. If TFT-LCD panel with backlight is used for the LVP, in order to achieve a better signal-to-noise ratio of solar cell photocurrent measurement, a uniform and stable light source with high light intensity is required of the backlight. For solar cell test and characterization, a dense two-dimensional array of LEDs can be used to provide an aerial light source with high light intensity. But the heat generation due to LED power consumption and/or the high dark photocurrent of a solar cell due to the leakage light through the LVP can limit the density of LED array. This limitation can be removed or loosened by making use of the fact that the divisional control of light transmittance by the LVP does not always illuminate entire area of solar cell surface. In most operations of the divisional control by the LVP, partial areas (subsections) of a solar cell is illuminated and the required role of the backlight is to provide a uniform aerial light to the local area fully covering the partial solar cell surface to be illuminated. FIG. 9 shows an example of the zonal illumination by the backlight. The zone1 97 shows one of the zones to which a portion of backlight illuminates and the subsection4 98 shows one of the subsections to which the LVP transmits the light from the backlight through the corresponding bright image window. In this example the backlight area of zone 1 can be turned on to provide the uniform aerial light source for the subsections 1, 2, 3, 5, 6, and 7 and the backlight area of zone 2 can be turned on to provide the uniform aerial light source for the subsections 10, 11, 12, 14, 15, and 16. Thus the partial driving of the LED array can reduce the heat generation and the dark photocurrent of a solar cell without diminishing the advantage of high signal-to-noise ratio achieved by a dense two-dimensional array of LEDs. FIG. 10 shows an example of a LED array and its driving circuitry for matrix driving of LEDs. LED11 100, a LED or a group of LEDs, is selected for its light emission by closing a corresponding switch SWC1 in the column control switch group 105 and another corresponding switch SWR1 in the row control switch group 109. If another column control switch SWC2 is closed at the same time, then LED12 is also selected for its light emission. One can see that multiple LED Drivers in place of single LED Driver can increase the number of LEDs that are selected at the same time. The column control switch groups 105/106 are controlled by their respective control signal generators 107/108 and provide the connection between the LED anodes and their respective LED drivers 101/102. The row control switch groups 109/110 are controlled by their respective control signal generators 111/112 and provide the connection between the LED cathodes and their respective grounds. The LED on/off control signal generator 103/104 can change the LED light emission intensity by changing the duty ratio of the LED driving currents.

I claim:

1. A method for testing the solar cell conversion performance, comprising:
applying the light to the solar cell surface by the multiple-scanning method;
measuring the photocurrent in response to the solar cell illumination by the multiple-scanning method; and
detecting a defect and finding its location based on the characteristic mapping of solar cell photocurrent obtained during said measuring step.

2. The method of claim 1, wherein the multiple-scanning method is done through the divisional control of light transmittance by the light valve panel.

3. The method of claim 2, wherein the light valve panel is a flat-panel display.

4. The method of claim 1, wherein the defect is the solar cell subsection with abnormally low photocurrent below a critical value.

5. The method of claim 1, wherein the probe contacts can be made to the emitter and base electrodes of entire solar cell for photocurrent measurement of each sub solar cell, even when serially configured thin-film solar cell is tested, by scanning a sub solar cell while illuminating entire surface areas of other sub solar cells.

6. The method of claim 1, wherein minimizing the noise in the photocurrent measurement of the solar cell is done by the dark photocurrent cancellation method where the dark photocurrent is subtracted from the measured photocurrent.

7. The method of claim 1, wherein minimizing the noise in the photocurrent measurement due to non-uniform illumination of the light valve panel is done by the photocurrent calibration method where the conversion efficiency of the solar cell subsection is obtained by dividing the corresponding solar cell photocurrent by the light intensity of the light valve panel illuminating the solar cell subsection.

8. The method of claim 7, wherein the light intensity of the light valve panel illuminating a solar cell subsection is obtained by the multiple photocurrent measurement method where the photocurrent is measured for many number of solar cells and its average value is used to obtain a constant conversion efficiency of the solar cell subsection with respect to its location.

9. The method of claim 1, wherein decreasing the heat generation due to backlight power consumption and the dark photocurrent of a solar cell due to the leakage light through the light valve panel is done by the partial illumination of the solar cell through the zonal illumination of the backlight.

10. The method of claim 9, wherein the zonal illumination of the backlight is done by a LED array and its driving circuitry for matrix driving of LEDs.

11. A system for testing the solar cell conversion performance, comprising:
an optical signal generator which applies the light to the solar cell surface by the multiple-scanning method;
a current meter which measures the photocurrent in response to the solar cell illumination by the multiple-scanning method; and
a controller, wherein the controller:
controls the optical signal generator,
controls the current meter, and
detects a defect and finds its location based on the characteristic mapping of solar cell photocurrent measured by said current meter.

12. The system of claim 11, wherein the multiple-scanning method is done through the divisional control of light transmittance by the light valve panel.

13. The system of claim 12, wherein the light valve panel is a flat-panel display.

14. The system of claim 11, wherein the controller identifies and reports a defect when a solar cell subsection has abnormally low photocurrent below a critical value.

15. The system of claim 11, wherein the probe contacts of the current meter can be made to the emitter and base electrodes of entire solar cell for photocurrent measurement of each sub solar cell, even when serially configured thin-film solar cell is tested, by scanning a sub solar cell while illuminating entire surface areas of other sub solar cells.

16. The system of claim 11, wherein the controller minimizes the noise in the photocurrent measurement of the solar cell by the dark photocurrent cancellation method where the dark photocurrent is subtracted from the measured photocurrent.

17. The system of claim 11, wherein the controller minimizes the noise in the photocurrent measurement of the solar cell by the photocurrent calibration method where the conversion efficiency of the solar cell subsection is obtained by dividing the corresponding solar cell photocurrent by the light intensity of the light valve panel illuminating the solar cell subsection.

18. The system of claim 17, wherein the controller obtains the light intensity of the light valve panel illuminating a solar cell subsection by the multiple photocurrent measurement method where the photocurrent is measured for many number of solar cells and its average value is used to obtain a constant conversion efficiency of the solar cell subsection with respect to its location.

19. The system of claim 11, wherein the controller controls the optical signal generator to decrease the heat generation due to backlight power consumption and the dark photocurrent of a solar cell due to the leakage light through the light valve panel based on the partial illumination of the solar cell through the zonal illumination of the backlight.

20. The system of claim 9, wherein the zonal illumination of the backlight is done by a LED array and its driving circuitry for matrix driving of LEDs.
